(19) United States
(12) Patent Application Publication
(10) Pub. No.: US 2024/0049398 A1
(43) Pub. Date: Feb. 8, 2024

(54) WIRING SUBSTRATE AND METHOD FOR MANUFACTURING WIRING SUBSTRATE

(71) Applicant: IBIDEN CO., LTD., Ogaki (JP)

(72) Inventors: Toshiki FURUTANI, Ibi-gun (JP); Jun SAKAI, Ibi-gun (JP)

(73) Assignee: IBIDEN CO., LTD., Ogaki (JP)

(21) Appl. No.: 18/365,453

(22) Filed: Aug. 4, 2023

(30) Foreign Application Priority Data
Aug. 5, 2022 (JP) 2022-125674

(51) Int. Cl. H05K 3/24; H05K 3/46; H05K 3/10; H05K 1/11; H05K 1/09

(52) U.S. Cl. CPC H05K 3/241; H05K 3/4605; H05K 3/108; H05K 1/115; H05K 1/092

(57) ABSTRACT

A wiring substrate includes an insulating layer, and a conductor layer formed on a surface of the insulating layer and including wiring patterns such that the conductor layer has a polished surface on the opposite side with respect to the insulating layer and includes an upper layer including a plating film and a lower layer including a seed layer for the plating film and directly formed on the surface of the insulating layer. The conductor layer is formed such that a ratio of a thickness of the lower layer to a thickness of the conductor layer is 2.5% or less, the wiring patterns have the minimum wiring width of 5 μm or less and the minimum inter-wiring distance of 7 μm or less, and each of the wiring patterns has an aspect ratio in a range of 2.0 to 4.0.

### CROSS-REFERENCE TO RELATED APPLICATIONS

The present application is based upon and claims the benefit of priority to Japanese Patent Application No. 2022-125674, filed Aug. 5, 2022, the entire contents of which are incorporated herein by reference.

### BACKGROUND OF THE INVENTION

### Field of the Invention

The present invention relates to a wiring substrate and a method for manufacturing a wiring substrate.

### Description of Background Art

Japanese Patent Application Laid-Open Publication No. 2009-253147 describes a method for forming a wiring on an insulating layer by electrolytic plating.

### SUMMARY OF THE INVENTION

According to one aspect of the present invention, a wiring substrate includes an insulating layer, and a conductor layer formed on a surface of the insulating layer and including wiring patterns such that the conductor layer has a polished surface on the opposite side with respect to the insulating layer and includes an upper layer including a plating film and a lower layer including a seed layer for the plating film and directly formed on the surface of the insulating layer. The conductor layer is formed such that a ratio of a thickness of the lower layer to a thickness of the conductor layer is 2.5% or less, the wiring patterns have the minimum wiring width of 5 μm or less and the minimum inter-wiring distance of 7 μm or less, and each of the wiring patterns has an aspect ratio in a range of 2.0 to 4.0.

According to another aspect of the present invention, a method for manufacturing a wiring substrate includes forming an insulating layer, and forming a conductor layer on a surface of the insulating layer. The forming of the conductor layer includes forming a seed layer having a thickness in the range of 0.03 μm to 0.3 μm on the surface of the insulating layer, forming, on the seed layer, a plating resist having groove-shaped openings exposing the seed layer, forming, in the groove-shaped openings, an electrolytic plating film such that the electrolytic plating film is thicker than the plating resist and that each of the groove-shaped openings has a width of 5 μm or less, an aspect ratio of 2.0 or more, and a distance of 7 μm or less between adjacent ones of the groove-shaped openings, polishing the electrolytic plating film and the plating resist such that a thickness of the electrolytic plating film and a thickness of the plating resist are reduced and that the thickness of the seed layer does not exceed 2.5% of a total thickness of the seed layer and the electrolytic plating film, removing the plating resist from the seed layer, and removing a portion of the seed layer that is not covered by the electrolytic plating film.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is an enlarged view of a portion (II) of FIG. 1;

FIG. 3 is an enlarged cross-sectional view illustrating an example of a wiring pattern included in a wiring substrate according to an embodiment of the present invention;

FIG. 4A is a cross-sectional view illustrating the wiring substrate of FIG. 1 in a process of being manufactured using a method for manufacturing a wiring substrate according to an embodiment of the present invention;

FIG. 4B is a cross-sectional view illustrating the wiring substrate of FIG. 1 in a process of being manufactured using a method for manufacturing a wiring substrate according to an embodiment of the present invention;

FIG. 4C is a cross-sectional view illustrating the wiring substrate of FIG. 1 in a process of being manufactured using a method for manufacturing a wiring substrate according to an embodiment of the present invention;

FIG. 4D is a cross-sectional view illustrating the wiring substrate of FIG. 1 in a process of being manufactured using a method for manufacturing a wiring substrate according to an embodiment of the present invention;

FIG. 4E is a cross-sectional view illustrating the wiring substrate of FIG. 1 in a process of being manufactured using a method for manufacturing a wiring substrate according to an embodiment of the present invention;

FIG. 4F is a cross-sectional view illustrating the wiring substrate of FIG. 1 in a process of being manufactured using a method for manufacturing a wiring substrate according to an embodiment of the present invention;

FIG. 4G is a cross-sectional view illustrating the wiring substrate of FIG. 1 in a process of being manufactured using a method for manufacturing a wiring substrate according to an embodiment of the present invention;

FIG. 4H is a cross-sectional view illustrating the wiring substrate of FIG. 1 in a process of being manufactured using a method for manufacturing a wiring substrate according to an embodiment of the present invention;

FIG. 4I is a cross-sectional view illustrating the wiring substrate of FIG. 1 in a process of being manufactured using a method for manufacturing a wiring substrate according to an embodiment of the present invention;

FIG. 4J is a cross-sectional view illustrating the wiring substrate of FIG. 1 in a process of being manufactured using a method for manufacturing a wiring substrate according to an embodiment of the present invention;

FIG. 4K is a cross-sectional view illustrating the wiring substrate of FIG. 1 in a process of being manufactured using a method for manufacturing a wiring substrate according to an embodiment of the present invention;

FIG. 5 is a cross-sectional view illustrating an example of a wiring substrate according to another embodiment of the present invention;

FIG. 6A is a cross-sectional view illustrating the wiring substrate of FIG. 5 in a process of being manufactured using a method for manufacturing a wiring substrate according to an embodiment of the present invention; and

FIG. 6B is a cross-sectional view illustrating the wiring substrate of FIG. 5 in a process of being manufactured using a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### First Embodiment

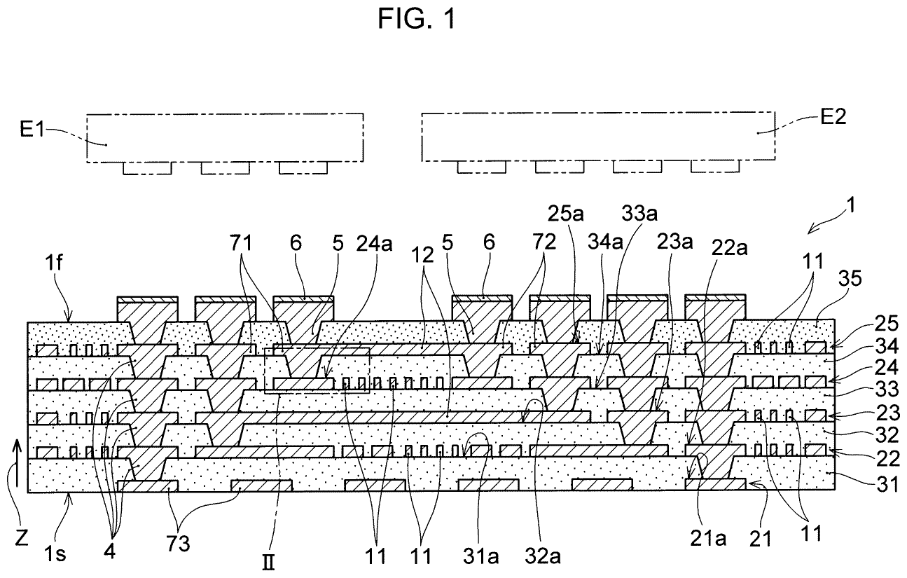

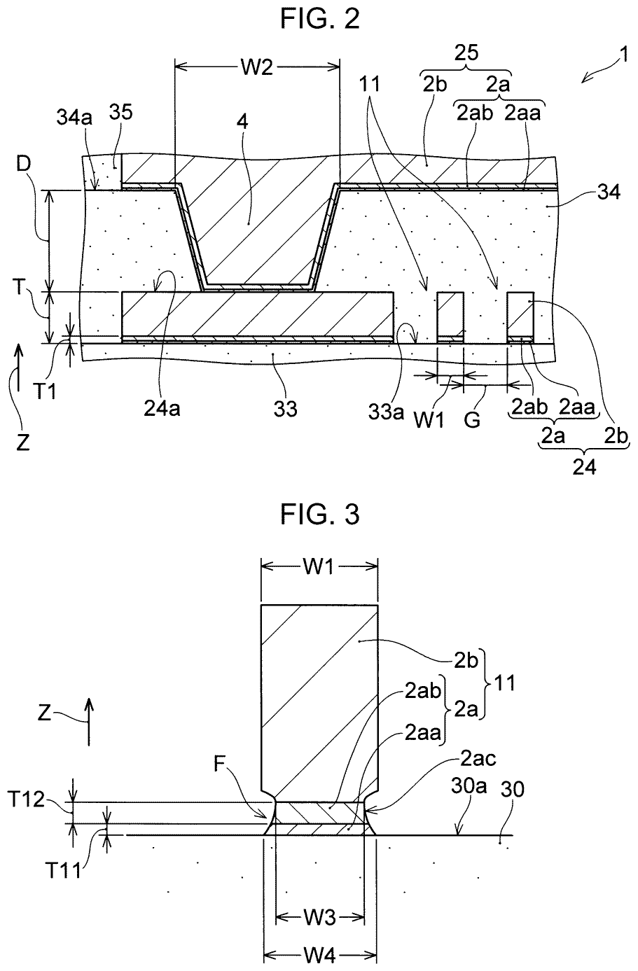

A wiring substrate according to an embodiment of the present invention is described with reference to the drawings. FIG. 1 illustrates a cross-sectional view of a wiring substrate 1, which is an example of the wiring substrate of the present embodiment. FIG. 2 illustrates an enlarged view of a portion (II) of FIG. 1. The wiring substrate 1 is merely an example of the wiring substrate of the embodiment. For example, a laminated structure of the wiring substrate of the embodiment, and the number of conductor layers and the number of insulating layers included in the wiring substrate of the embodiment are not limited to the laminated structure of the wiring substrate 1 of FIG. 1, and the number of conductor layers and the number of insulating layers included in the wiring substrate 1. Further, in the drawings to be referenced in the following description, in order to facilitate understanding of an embodiment to be disclosed, a specific portion may be depicted in an enlarged manner and structural elements may not be depicted in precise proportions in terms of size or length relative to each other.

As illustrated in FIG. 1, the wiring substrate 1 has a first surface (1f), which is one of two surfaces (main surfaces) orthogonal to a thickness direction of the wiring substrate 1, and a second surface (1s) on the opposite side with respect to the first surface (1f) and includes insulating layers and conductor layers laminated in the thickness direction of the wiring substrate 1. The wiring substrate 1 of the example of FIG. 1 includes insulating layers (31-35) and conductor layers (21-25). Among the conductor layers (21-25), the conductor layer 21 is formed on an outermost side on the second surface (1s) side of the wiring substrate 1. Surfaces of the conductor layer 21 other than a surface on the second surface (1s) side are covered by the insulating layer 31. Then, on a surface of the insulating layer 31 on the first surface (1f) side, in an order toward the first surface (1f), the conductor layer 22, the insulating layer 32, the conductor layer 23, the insulating layer 33, the conductor layer 24, the insulating layer 34, the conductor layer 25, and the insulating layer 35 are formed.

The conductor layers (22-25) are respectively formed on surfaces of the insulating layers (31-34) on the first surface (1f) side of the wiring substrate 1. The conductor layer 22 is formed on a surface (31a) of the insulating layer 31, the conductor layer 23 is formed on a surface (32a) of the insulating layer 32, the conductor layer 24 is formed on a surface (33a) of the insulating layer 33, and the conductor layer 25 is formed on a surface (34a) of the insulating layer 34. The conductor layer 25 is an outermost conductor layer on the first surface (1f) side of the wiring substrate 1. The first surface (1f) of the wiring substrate 1 is mainly formed of a surface of the insulating layer 35, which covers the conductor layer 25, the surface facing the opposite direction with respect to the conductor layer 25. On the other hand, the second surface (1s) of the wiring substrate 1 is formed of surfaces of the conductor layer 21 and the insulating layer 31, the surfaces facing the opposite direction with respect to the conductor layer 22. The wiring substrate 1 of the example of FIG. 1 is a so-called build-up wiring substrate manufactured by sequentially forming the conductor layers (21-25) and the insulating layers (31-35).

In the description of the present embodiment, in the thickness direction of the wiring substrate 1 (lamination direction of the insulating layers and the conductor layers), the first surface (1f) side is also referred to as an “upper side” or simply “upper,” and the second surface (1s) side is also referred to as a “lower side” or simply “lower.” Further, for the conductor layers and the insulating layers, a surface facing the first surface (1f) side is also referred to as an “upper surface,” and a surface facing the second surface (1s) side is also referred to as a “lower surface.” Further, the thickness direction of the wiring substrate of the embodiment is also simply referred to as a “Z direction.”

The wiring substrate 1 of the embodiment further includes via conductors 4 that each penetrate one of the insulating layers (31-34). The wiring substrate 1 in FIG. 1 includes the multiple via conductors 4 that each penetrate one of the insulating layers (31-34). Each of the via conductors 4 is integrally formed with a conductor layer formed on an upper side of the each of the via conductors. Each of the via conductors 4 connects two conductors sandwiching one of the insulating layers (31-34), which is penetrated by the each of the via conductors 4. For example, the via conductors 4 penetrating the insulating layer 33 are integrally formed with the conductor layer 24 and connect the conductor layer 24, which is a conductor, and a conductor (in the example of FIG. 1, the conductor layer 23) positioned on one side of the insulating layer 33 opposite to the conductor layer 24. Similarly, the via conductors 4 penetrating the insulating layer 31 connect the conductor layer 21 and the conductor layer 22, the via conductors 4 penetrating the insulating layer 32 connect the conductor layer 22 and the conductor layer 23, and the via conductors 4 penetrating the insulating layer 34 connect the conductor layer 24 and the conductor layer 25. Each of the via conductors 4 has a tapered shape that is reduced in width from the first surface (1f) side toward the second surface (1s) side of the wiring substrate 1. The “width” of each of the via conductors 4 is the longest distance between two points on an outer perimeter of a cross section (or an end surface) of the each of the via conductors 4 that is orthogonal to the Z direction.

Each of the conductor layers (21-25) includes predetermined conductor patterns. In the example of FIG. 1, the conductor layer 25 includes multiple conductor pads 71 and multiple conductor pads 72, which are connected to components (a first component (El) and a second component (E2) in the example of FIG. 1) mounted on the wiring substrate 1 when the wiring substrate 1 is used. The first component (E1) and the second component (E2) mounted on the wiring substrate 1 can be electronic components such as semiconductor integrated circuit devices such as microcomputers and memories.

The wiring substrate 1 of FIG. 1 further includes multiple conductor posts 5 formed on surfaces of the conductor pads 71 or the conductor pads 72. The conductor posts 5 penetrate the insulating layer 35 and protrude from the upper surface of the insulating layer 35, which forms the first surface (1f) of the wiring substrate 1. On the upper surface of the insulating layer 35, no conductor layer is formed and there are no conductors other than the conductor posts 5. By the conductor posts 5, the components (the first component (E1) and the second component (E2) in the example of FIG. 1) mounted on the wiring substrate 1 are connected to the conductor pads 71 or the conductor pads 72. Since the first component (E1) and the second component (E2) are connected to the wiring substrate 1 via the conductor posts 5, it may be possible that the mounting of the components is facilitated and a short circuit between the conductor pads 71 or a short circuit between the conductor pads 72 is prevented.

On end surfaces of the conductor posts 5 on the opposite side with respect to the conductor layer 25, a functional layer 6 is formed that can function as a protective layer of the end surfaces of the conductor posts 5 and/or a bonding layer between the first component (E1) or the second component (E2) and the conductor posts 5. The functional layer 6 is formed of, for example, a plating film of nickel, tin, palladium, gold, or the like.

On the other hand, the conductor layer 21, of which a lower surface is exposed on the second surface (1s) of the wiring substrate 1, includes conductor pads 73. The conductor pads 73 are connected to conductors (not illustrated) external to the wiring substrate 1, for example, pads of a wiring substrate other than the wiring substrate 1, such as a motherboard of an electronic device, or any conductive mechanism components, or the like. In the example of FIG. 1, the conductor pads 71 and the conductor pads 72 of the conductor layer 25 and the conductor pads 73 of the conductor layer 21 are connected via multiple stacked via conductors 4 (so-called stacked via conductors). Therefore, when the wiring substrate 1 is used, the first component (E1) and the second component (E2) are connected via short paths to a member connected to the conductor pads 73, such as a motherboard, and it may be possible that intended electrical characteristics can be easily obtained.

The conductor layer 25 includes conductor patterns 12 and multiple wiring patterns 11 in addition to the conductor pads 71 and the conductor pads 72. As illustrated in FIG. 1, the conductor pattern 12 connects the conductor pads 71 and the conductor pads 72. Although not illustrated, the wiring patterns 11 can be signal lines that connect any conductor pads included in any of the conductor layers (21-25) to propagate electrical signals.

The conductor layers other than the conductor layer 25 also may include any desired conductor patterns. In the example of FIG. 1, each of the conductor layers (22-24) also includes multiple wiring patterns 11, and the conductor layer 23 further includes a conductor pattern 12. Two ends of the conductor pattern 12 included in the conductor layer 23 are respectively connected to one of the conductor pads 71 and one of the conductor pads 72 via the via conductors 4. Similar to the wiring patterns 11 included in the conductor layer 25, the multiple wiring patterns 11 included in each of the conductor layers (22-24) are signal lines that each connect any conductor pads to propagate electrical signals.

In the wiring substrate of the embodiment, among one or more conductor layers included in the wiring substrate of the embodiment, such as the conductor layers (21-25), at least one conductor layer has a polished surface in a state of having been polished as a surface on the opposite side with respect to the insulating layer on which the conductor layer is formed. For example, in the example of FIG. 1, a surface (24a), which is a surface of the conductor layer 24 on the opposite side with respect to the insulating layer 33, is a polished surface. In the example of FIG. 1, for all the conductor layers (22-25), a surface on the first surface (1f) side of the wiring substrate 1 is a polished surface. That is, in addition to the surface (24a) of the conductor layer 24, a surface (22a) of the conductor layer 22 on the opposite side with respect to the insulating layer 31, a surface (23a) of the conductor layer 23 on the opposite side with respect to the insulating layer 32, and a surface (25a) of the conductor layer 25 on the opposite side with respect to the insulating layer 34 are polished surfaces.

Therefore, each of the surfaces (22a-25a) has, for example, a surface roughness lower than that of a plating film formed as is by metal deposition. Therefore, it is thought that, in the wiring patterns 11 included in the conductor layers (22-25) having polished surfaces, deterioration of signal transmission characteristics or an increase in voltage drop due to a substantial increase in conductor resistance due to a skin effect during transmission of high-frequency signals is unlikely to occur. For example, the polished surface of the conductor layers (22-25) as a surface on the first surface (1f) side can have an arithmetic mean roughness of 0.3 μm or less. When such a surface roughness is obtained, it may be possible that the favorable effect described above regarding transmission characteristics can be obtained. Further, in the wiring substrate 1 of FIG. 1, a surface (21a) of the conductor layer 21 on the first surface (1f) side of the wiring substrate 1 also may be a polished surface.

Further, each of the surfaces (21a-25a), which are polished surfaces, is likely to have a uniform height over the entire conductor layer having the each of the surfaces (21a-25a) (the height being a distance from the upper surface of the insulating layer on the lower side of the conductor layer, for example, a distance between the surface (33a) of the insulating layer 33 and the surface (24a) of the conductor layer 24). Therefore, the via conductors 4 formed on each conductor layer, for example, on the conductor layer 24, also are likely to be aligned in height, and further, the conductor posts 5 formed thereon also are likely to be aligned in height. As a result, it is thought that the first component (E1) and/or the second component (E2) can be stably mounted on the wiring substrate 1. Further, since the surfaces (22a-25a) are polished surfaces, each of the wiring patterns 11 is likely to have a substantially constant thickness over its entire length, and thus, a characteristic impedance of each of the wiring patterns 11 is unlikely to fluctuate. Therefore, it may be possible that a reflection loss in the wiring patterns 11 is suppressed.

As illustrated in FIG. 2, the wiring patterns 11 included in the conductor layers of the wiring substrate 1 have a wiring width (W1) and a distance (G) between adjacent wiring patterns 11. Since FIG. 2 illustrates an enlarged view of the portion (II) of FIG. 1, the wiring patterns 11 of the conductor layer 24, the conductor layer 25, the via conductors 4 penetrating the insulating layer 34, and the like are illustrated enlarged. A minimum value of the wiring width (W1) of the multiple wiring patterns 11 included in the conductor layers included in the wiring substrate 1 of the present embodiment is 1 μm or more and 5 μm or less, and a minimum value of the distance (G) between adjacent wiring patterns 11 is 3 μm or more and 7 μm or less. That is, at least one of conductor layers such as the conductor layers (22-25) included in the wiring substrate 1 of the embodiment includes wiring patterns that have a wiring width of 5 μm or less and a distance of 7 μm or less between adjacent wiring patterns. In the example of FIGS. 1 and 2, some or all of the conductor layers (22-25) include wiring patterns 11 that have a wiring width (W1) of 1 μm or more and 5 μm or less, and a distance (G) of 3 μm or more and 7 μm or less between adjacent wiring patterns 11.

In the present embodiment, at least one of conductor layers such as the conductor layers (22-25) includes wiring patterns that have such fine minimum line width and minimum inter-wiring distance, that is, wiring patterns formed at a fine pitch. Therefore, it may be possible that the wiring substrate of the embodiment can be realized smaller than a conventional wiring substrate. Further, in designing the wiring substrate of the embodiment, which can have wiring patterns with such fine wiring width and inter-wiring distance between conductor pads to be connected to components, it may be possible that a degree of freedom in arranging two components is high.

In addition, in the present embodiment, wiring patterns such as the wiring patterns 11, which can have such a fine wiring width, have a thickness (T) larger than the wiring width (W1). In other words, in the present embodiment, the wiring patterns such as the wiring patterns 11 included in the conductor layers have a relatively large aspect ratio ((the thickness (T) of the wiring patterns)/(the width (W1) of the wiring patterns)) exceeding 1. Specifically, the wiring patterns included in the wiring substrate of the present embodiment have an aspect ratio of 2.0 or more and 4.0 or less. In the example of FIG. 1, some or all of the conductor layers (22-25) can include the wiring patterns 11 having an aspect ratio of 2.0 or more and 4.0 or less.

Wiring patterns having such a large aspect ratio can have a low conductor resistance for a small wiring width. Therefore, it may be possible that wiring patterns (for example, the wiring patterns 11) connecting conductor pads to be connected to an electronic component, such as the conductor pads 71 in the example of FIG. 1, have low insertion loss. Therefore, it may be possible that signals can be propagated between two electronic components such as the first component (E1) and the second component (E2) with little transmission loss, that is, with good transmission efficiency. Further, it may be possible that a desired characteristic impedance in signal lines that connect two electronic components can be easily obtained, and thus, the insertion loss can be further reduced.

In the example of FIGS. 1 and 2, the thickness (T) of the wiring pattern 11 included in the conductor layers, that is, the thickness (T) of each of the conductor layers (22-25) can be, for example, 5 μm or more and 15 μm or less. When such a thickness is obtained, it may be possible that the effect such as the reduction in insertion loss as described above can be obtained without significantly increasing the thickness of the wiring substrate of the embodiment.

In the wiring substrate 1 of the present embodiment, which includes the wiring patterns 11 that can be formed at a relatively fine pitch, via conductors 4 formed at a small pitch may be preferable. That is, via conductors 4 having a small width and thus a large aspect ratio may be preferable. In the wiring substrate 1 of the embodiment, the via conductors 4 can have an aspect ratio of, for example, 0.5 or more and 1.0 or less. It may be possible that wiring patterns such as the wiring patterns 11 formed at a fine pitch can be connected to wiring patterns of a conductor layer different from the conductor layer that includes the wiring patterns formed at a fine pitch, while maintaining a relatively fine pitch even at connection parts between the conductor layers. The aspect ratio of the via conductors 4 is (distance (D) illustrated in FIG. 2)/(width (W2) illustrated in FIG. 2). Here, the distance (D) is a distance in the Z direction between the two conductor layers connected by a via conductor 4, and the width (W2) is a width of the via conductor 4 at an interface with the conductor layer on the first surface (1f) side (see FIG. 1).

Each of the insulating layers (31-34) is an interlayer insulating layer interposed between two conductor layers and may be formed using an insulating resin. Examples of the insulating resin include: thermosetting resins such as epoxy resins, bismaleimide triazine resins (BT resins), or phenolic resins; and thermoplastic resins such as fluorine resins, liquid crystal polymers (LCP), fluoroethylene (PTFE) resins, polyester (PE) resins, and modified polyimide (MPI) resins. Each of the insulating layers (31-34) may contain an inorganic filler (not illustrated) such as silica, or alumina. Each of the insulating layers (31-34) may also contain a reinforcing material (core material) such as a glass fiber (not illustrated). However, from a point of view of facilitating formation of the wiring patterns 11 formed at a fine pitch, it may be preferable that a reinforcing material is not contained.

When each of the insulating layers (31-34) contains an inorganic filler, it is thought that an inorganic filler having small particle sizes (a particle size of an inorganic filler particle is a longest distance between two points on a surface of the inorganic filler particle) is preferable. For example, each of the insulating layers (31-34) may contain multiple inorganic filler particles having a maximum particle size of 1 μm or less. When the particle sizes of the inorganic filler contained in each insulating layer are small, for example, even between the wiring patterns 11 formed at a fine pitch, it may be possible that a short circuit failure due to a leak path or the like along an inorganic filler particle is unlikely to occur. Further, it may be possible that small-sized via conductors 4 can be easily formed.

Further, it is thought that, in order to obtain good high-frequency signal transmission characteristics in the wiring patterns included in the conductor layers, the insulating layers (31-34) having low dielectric constant and dielectric loss are preferable. For example, for each of the insulating layer (31-34), a relative permittivity can be about 3.0 or more and 4.0 or less and a dielectric loss tangent can be about 0.001 or more and 0.0005 or less at a frequency of 5.8 GHz.

The insulating layer 35 covering the conductor layer 25 can also be formed using the same insulating resin as the insulating layers (31-34). However, the insulating layer 35 covering the conductor layer 25 may be an insulating layer functioning as a solder resist. In this case, the insulating layer 35 may be formed of a material of which a main component or an additive is different from that of the insulating layers (31-34). For example, the insulating layer 35 may be formed using an epoxy resin or polyimide resin or the like containing a photosensitive agent.

The conductor layers (21-25), the via conductors 4, and the conductor posts 5 are formed, for example, using any metal such as copper or nickel. The conductor layer 21 is formed of, for example, a single-layer metal film formed of an electrolytic plating film. The conductor layer 21 is embedded in the insulating layer 31 and only a surface thereof on the second surface (1s) side is exposed.

Each of the conductor layers (22-25), via conductors 4, and conductor posts 5 is depicted in a simplified manner as having only one layer in FIG. 1 but may have a multilayer structure including two or more metal films that are each formed by plating or sputtering or the like, such as the conductor layer 24 and the conductor layer 25, and the via conductor 4, illustrated in FIG. 2, which is an enlarged view. Specifically, each of the conductor layers (such as the conductor layers (22-25)) and via conductors 4 included in the wiring substrate of the embodiment is formed by a lower layer (2a) and an upper layer (2b) formed on the lower layer (2a). Therefore, each of the wiring patterns 11 included in the conductor layers is also formed of the lower layer (2a) and the upper layer (2b).

The upper layer (2b) is formed entirely on the lower layer (2a), that is, on the first surface (1f) (see FIG. 1) side of the wiring substrate 1 with respect to the lower layer (2a). A surface of the upper layer (2b) on the first surface (1f) side is a polished surface that each of the conductor layers (22-25) described above can have. The lower layer (2a) is interposed between the upper layer (2b) and the insulating layer immediately below the upper layer (2b) (for example, between the upper layer (2b) of the conductor layer 24 and the insulating layer 33). The lower layer (2a) is directly formed on the surface of each insulating layer on the first surface (1f) side, such as the surface (33a) of the insulating layer 33, the surface (34a) of the insulating layer 34, or the like.

The lower layer (2a) is formed of a metal film formed using any method. The lower layer (2a) is, for example, a sputtering film formed by sputtering, or may be an electroless plating film formed by electroless plating. On the other hand, the upper layer (2b) is formed of a plating film formed by electrolytic plating. The lower layer (2a) is a seed layer for the upper layer (2b) formed by the electrolytic plating. That is, the lower layer (2a) is a metal film that functions as an electrode allowing a plating current to pass when the upper layer (2b) is formed by electrolytic plating and functions as a seed layer (or a power feeding layer) that can facilitate plating metal deposition.

Then, in the wiring substrate of the present embodiment, each conductor layer has a lower layer (2a) with a sufficiently small thickness relative to the thickness of each conductor layer. Specifically, a ratio of a thickness (T1) of the lower layer (2a) to the thickness (T) of each of the conductor layers (22-25) included in the wiring substrate 1 of the embodiment is 0.2% or more and 2.5% or less. Advantages of the relatively thin lower layer (2a) are described below.

In the formation of each conductor layer, such as the conductor layer 24, including the formation of the upper layer (2b) using the lower layer (2a) as a seed layer (or power feeding layer), as will be described later, first, the lower layer (2a) functioning as a seed layer is formed on the entire surface of each insulating layer, such as the surface (33a) of the insulating layer 33. After the formation of the upper layer (2b) by pattern plating including electrolytic plating, a portion (unwanted portion) of the lower layer (2a) formed on the entire surface of each insulating layer that is not covered by the upper layer (2b) is removed by quick etching or the like. In removing the unwanted portion of the lower layer (2a), when the lower layer (2a) is thick, it may be possible that the unwanted portion is not sufficiently removed within a predetermined etching time. As a result, it may be possible that a short circuit failure occurs between the wiring patterns 11 that can be formed at fine inter-wiring distances, or insulation between the wiring patterns 11 deteriorates. Further, when the etching is performed for an excessive time to prevent a short circuit or deterioration in insulation, it may be possible that the etching on the upper layer (2b) progresses, the upper layer (2b) decreases in width or height, and intended electrical characteristics cannot be obtained.

However, the lower layer (2a) of each conductor layer included in the wiring substrate of the present embodiment has a thickness that is a small fraction of the thickness of each conductor layer as described above. Therefore, an unwanted portion of the lower layer (2a) can be sufficiently removed in a short time by etching or the like. Therefore, a short circuit failure or deterioration in insulation between the wiring patterns 11 that can be formed at fine inter-wiring distances is unlikely to occur. Further, since an excessive etching time is not required for removing the lower layer (2a), the upper layer (2b) is unlikely to be reduced in width or height. In addition, in the present embodiment in which the lower layer (2a) has a thickness that is a small fraction of the thickness of each conductor layer as described above, it may be possible that the upper layer (2b) is thicker than one conventionally obtained. Therefore, even when the upper layer (2b) is slightly etched and is reduced in width or thickness to some extent in removing the unwanted part of the lower layer (2a), it may be possible that the conductor resistance of each conductor layer is unlikely to decrease to an extent that a substantial problem arises, and intended electrical characteristics are likely to be maintained.

When the lower layer (2a) has the above-described thickness (T1) that is 2.5% or less of the thickness (T) of each of the conductor layers such as the conductor layers (22-25), it may be possible that such effects of preventing a short circuit, ensuring desired electrical characteristics, and the like can be obtained. Further, when the lower layer (2a) has a thickness that is 0.2% or more of the thickness (T) of each of the conductor layers, it may be possible that, in forming the upper layer (2b), a sufficient plating current can be supplied for a desired thickness of the upper layer (2b), and a thick upper layer (2b) can be formed in a relatively short time.

Specifically, the thickness (T1) of the lower layer (2a) is, for example, 0.03 μm or more and 0.3 μm or less. When the thickness (T1) of the lower layer (2a) is 0.3 μm or less, it may be possible that the above-described effects of preventing a short circuit, ensuring desired electrical characteristics and the like can be obtained. Further, when the thickness (T1) is 0.03 μm or more, it may be possible that, in forming the upper layer (2b), an excessive voltage drop is unlikely to occur in the lower layer (2a), which is a power feeding layer, and thus, variation in the thickness of the upper layer (2b) is small.

As described above, the lower layer (2a) may be any metal film, such as a sputtering film. A sputtering film can be easily formed thin and with a uniform thickness, and thus, may be preferable as the lower layer (2a) having the above-described thickness ratio with respect to each conductor layer. Further, it may be possible that the upper surface of each of the conductor layers (22-25) has high flatness. In addition, when the lower layer (2a) is formed of a sputtering film, it may be possible that strong adhesion of the conductor layers such as the conductor layer 24 and the conductor layer 25 to the insulating layers such as the insulating layer 33 and the insulating layer 34 can be obtained. Further, since a sputtering film can adhere firmly to each insulating layer as described above, it may be possible that each insulating layer does not need to have large unevenness on its surface in order to obtain a so-called anchor effect. Therefore, it may be possible that the removal of the unwanted portion of the lower layer (2a) described above can be performed more quickly and sufficiently, and in each conductor layer, the effects of preventing a short circuit, ensuring desired electrical characteristics, suppressing a reduction in width or thickness of the wiring patterns, and the like can be more remarkably obtained.

When the lower layer (2a) is a sputtering film, as illustrated in FIG. 2, the sputtering film (lower layer (2a)) can include a lower film (2aa) and an upper film (2ab) formed on the lower film (2aa). The lower film (2aa) is directly formed on the surface of each insulating layer on the first surface (1f) side of the wiring substrate 1, such as the surface (33a) of the insulating layer 33, the surface (34a) of the insulating layer 34, or the like. The lower film (2aa) is, for example, a sputtering film formed of titanium, nickel, chromium, aluminum, or an alloy of copper with these or any other metals. On the other hand, the upper film (2ab) may be a sputtering film formed of copper. “Copper” means copper having a purity of 99.95% or higher. When the lower layer (2a) has the lower film (2aa) formed of a copper alloy or the like at an interface with each insulating layer such as the insulating layer 33, the upper film (2ab) formed of copper is likely to firmly adhere to each insulating layer via the lower film (2aa). Therefore, it may be possible that high adhesion strength between each conductor layer and each insulating layer can be obtained.

FIG. 3 illustrates an enlarged view of an example of a wiring pattern 11 included in the wiring substrate of the present embodiment on a further enlarged scale than FIG. 2. The wiring pattern 11 illustrated in FIG. 3 is formed on a surface (30a) of an insulating layer 30, which may be any of the insulating layers (31-34) illustrated in FIG. 1. The wiring pattern 11 illustrated in FIG. 3 also includes the lower layer (2a) and the upper layer (2b), and the lower layer (2a) includes the lower film (2aa) and the upper film (2ab). The lower film (2aa) has a thickness (T11) of, for example, about 0.01 μm or more and 0.3 μm or less, and the upper film (2ab) has a thickness (T12) of, for example, about 0.02 μm or more and 0.3 μm or less.

The wiring pattern 11 illustrated in FIG. 3 has a constriction (F) at a boundary portion between the lower layer (2a) and the upper layer (2b). That is, the boundary portion between the lower layer (2a) and the upper layer (2b) has a minimum width (W3) smaller than a width (W1) of a portion formed by the upper layer (2b). The lower layer (2a) has the minimum width (W3) at an upper end portion of the upper film (2ab) in the Z direction. That is, the upper film (2ab) has a width that widens from the upper layer (2b) side toward the lower film (2aa). In the entire portion from the upper film (2ab) to the insulating layer 30, a width (W4) of the lower film (2aa) in contact with the upper film (2ab) is smaller than the width (W1) of the upper layer (2b) excluding a portion of the constriction (F) (for example, a width of an upper end part, which is an end part on the opposite side with respect to the lower layer (2a) side), and is larger than the minimum width (W3) of the lower layer (2a) and the width of the upper film (2ab). The width of the lower film (2aa) increases from the upper film (2ab) side toward the insulating layer 30 side, and the lower film (2aa) has a fillet-like shape in the cross section illustrated in FIG. 3.

A side surface of each wiring pattern 11, in particular, a side surface (2ac) of the lower layer (2a) exposed on a side surface of each wiring pattern 11, may be a dissolution surface. That is, the side surface (2ac) is not, for example, a surface where metal deposited by plating is exposed as it is but is a surface that is exposed after removal of a portion dissolved by wet etching, dry etching, or the like, and exposes a state after disappearance of the dissolved portion. When the side surface (2ac) is a dissolution surface and as a result each wiring pattern 11 is constricted as in the example of FIG. 3, it may be possible that the insulating layer covering the wiring pattern 11, such as the insulating layer 34 (see FIG. 2), enters into the constricted portion (constriction (F)). Further, a contact area between each wiring pattern 11 and the insulating layer 30 is larger than a cross-sectional area at the constriction (F). Therefore, it may be possible that good adhesion between each wiring pattern 11 and the surrounding insulating layer such as the insulating layer 30 can be obtained. In addition, since a contact angle between the side surface of the lower film (2aa) forming each wiring pattern 11 and the surface (30a) of the insulating layer 30 is an obtuse angle, it may be possible that stress concentration on an outer periphery part of an interface between each wiring pattern 11 and the insulating layer 30 is relaxed. Therefore, it is thought that peeling between each wiring pattern 11 and the insulating layer 30 is unlikely to occur.

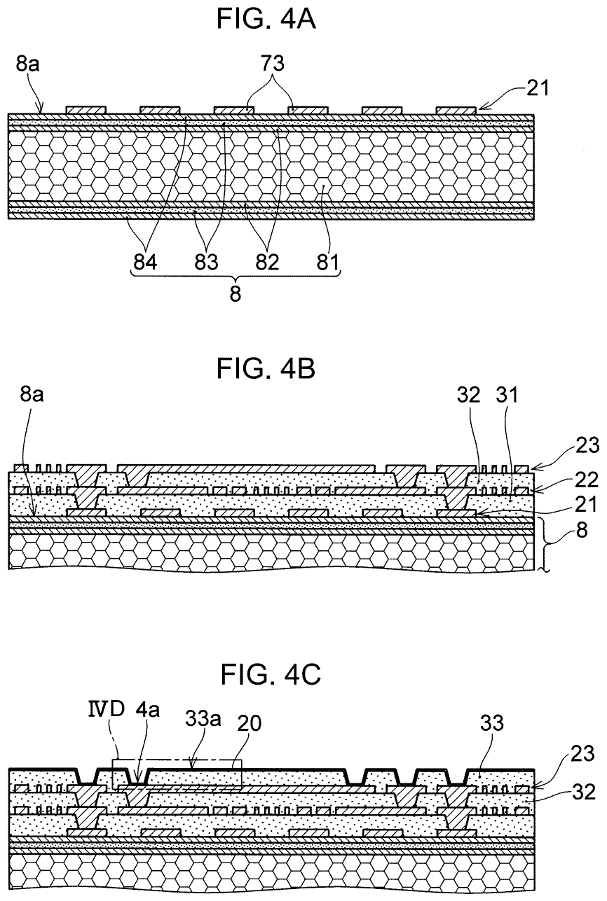

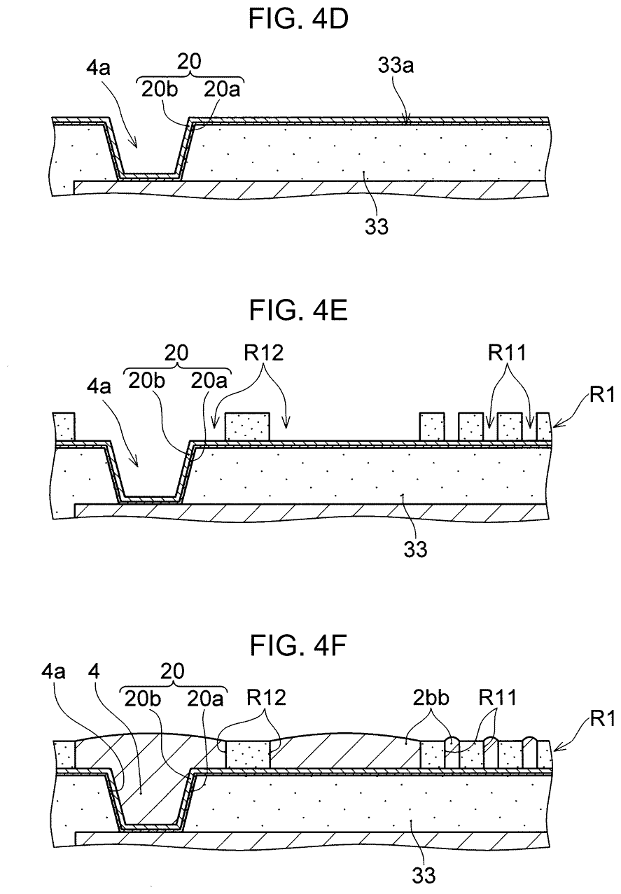

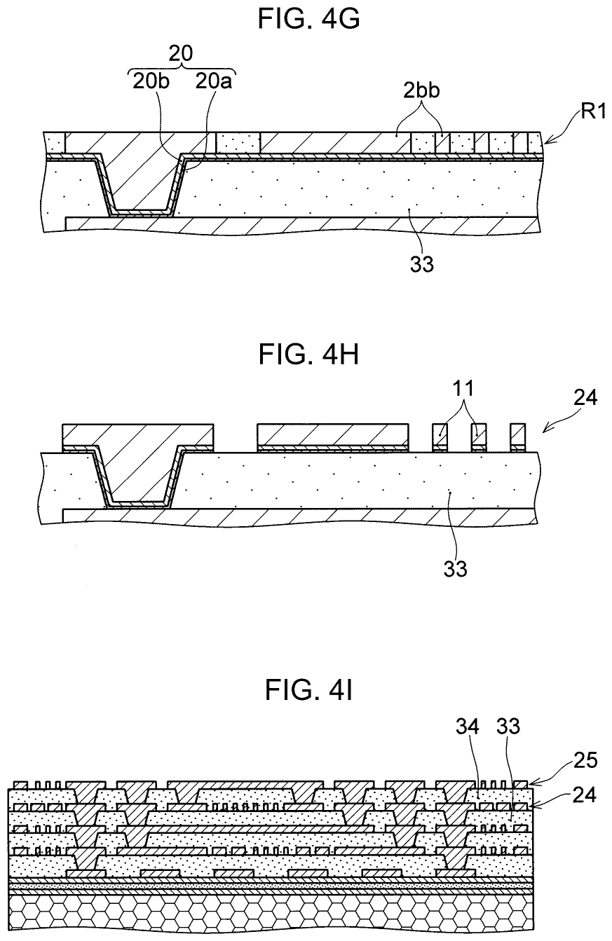

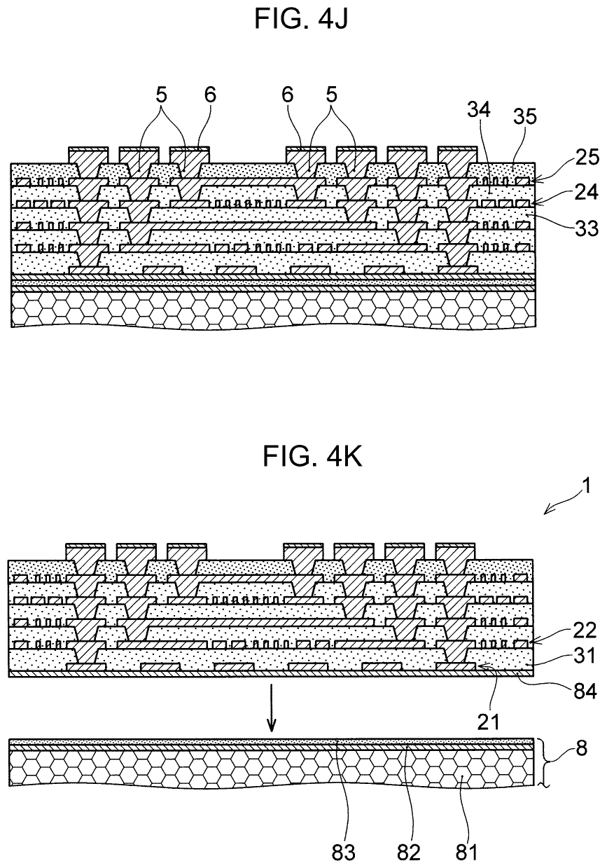

Next, with reference to FIGS. 4A-4K, an example of a method for manufacturing the wiring substrate of the embodiment is described using a case where the wiring substrate 1 illustrated in FIG. 1 is manufactured as an example. In the following, a method for manufacturing the wiring substrate 1 on a support 8 as illustrated in FIG. 4A is described. However, the method for manufacturing the wiring substrate of the present embodiment is not limited to a method in which the support 8 is used. Further, unless there is a description different from the description provided above regarding the materials of the structural elements of the wiring substrate 1, the structural elements may be formed using any of the materials described above with respect to the structural elements.

As illustrated in FIG. 4A, the support 8 is prepared, and the conductor layer 21 is formed on a surface (8a) of the support 8. In the example illustrated FIG. 4A, the support 8 including a base material 81, a first metal film layer 82, a release layer 83, and a second metal film layer 84 is prepared. The base material 81 is formed of, for example, an inorganic material such as glass or silicon having appropriate rigidity, or an organic material such as an epoxy resin. Each of the first and second metal film layers (82, 84) is formed of, for example, any metal such as copper. The release layer 83 may be formed of any material that allows the first metal film layer 82 and the second metal film layer 84 to be intentionally adhered to each other by a predetermined treatment and separated after that, and, for example, is formed of, for example, a thermoplastic or photosensitive adhesive or the like.

The conductor layer 21 is formed, for example, by pattern plating using electrolytic plating. On the second metal film layer 84, which forms the surface (8a) of the support 8, a plating resist (not illustrated) is provided having openings corresponding to the formation positions of the conductor patterns such as the conductor pads 73 to be included in the conductor layer 21. Then, by electrolytic plating using the second metal film layer 84 as a power feeding layer, a metal such as copper is deposited in the openings of the plating resist, and the conductor layer 21 is formed including conductor patterns formed of the deposited metal. After that, the plating resist is removed. Before the removal of the plating resist, the upper surface of the conductor layer 21 (the surface on the opposite side with respect to the support 8) may be polished, for example, using any method such as chemical mechanical polishing (CMP). When the polishing is performed, an upper surface portion of the plating resist before the removal may be polished together with the upper surface of the conductor layer 21.

As illustrated in FIG. 4B, on the surface (8a) of the support 8 and on the conductor layer 21, the insulating layer 31, the conductor layer 22, the insulating layer 32, and the conductor layer 23 are formed in this order. These insulating layers and conductor layers are formed using methods similar to the methods for forming the insulating layer 33 and the conductor layer 24 to be described below. In FIG. 4B, and in FIGS. 4C-4K to be referenced below, depiction about the opposite side with respect to the surface (8a) side of the support 8 is omitted. However, also on the opposite side with respect to the surface (8a) side of the support 8, the conductor layers (21-23) and the insulating layers (31, 32) may be formed in the processes illustrated in FIGS. 4A and 4B, and processing or formation of structural elements described with reference to FIGS. 4C-4K may be performed.

As illustrated in FIGS. 4C-4H, the method for manufacturing the wiring substrate of the present embodiment includes forming the insulating layer 33, and forming the conductor layer 24 on the surface (33a) of the insulating layer 33. First, as illustrated in FIG. 4C, the insulating layer 33 is formed on the insulating layer 32 and the conductor layer 23. The insulating layer 33 is formed, for example, by laminating and thermocompression bonding a film-like epoxy resin on the insulating layer 32 and the conductor layer 23. As described above, each insulating layer such as the insulating layer 33 may be formed using a thermosetting resin such as a BT resin or a phenol resin, or a thermoplastic resin such as a fluorine resin or LCP, in addition to an epoxy resin.

Through holes (4a) are formed in the insulating layer 33 at formation positions of the via conductors 4 (see FIG. 1) by irradiating CO₂ laser or the like. After the formation of the through holes (4a), preferably, a desmear treatment is performed in which resin residues (smears) remaining in the through holes (4a) are removed. The desmear treatment may be a wet treatment including immersion in a chemical solution such as a permanganate solution. However, the desmear treatment may also be a dry treatment. For example, a plasma treatment using a plasma gas such as argon, methane tetrafluoride, a mixture of methane tetrafluoride and oxygen, or sulfur hexafluoride may be performed as a dry treatment. In a desmear treatment by a plasma treatment, it may be possible that, compared to a wet treatment, erosion of the surface (33a) of the insulating layer 33 is suppressed.

Then, in the through holes (4a) and on the entire surface (33a) of the insulating layer 33, a seed layer 20 formed of, for example, copper or nickel or the like is formed, for example, by sputtering or electroless plating. By forming the seed layer 20 by sputtering, it may be possible that the seed layer 20 exhibiting high adhesion to the insulating layer 33 can be formed. The seed layer 20 functions as a power feeding layer when an electrolytic plating film (2bb) (see FIG. 4F) is formed in a subsequent process.

In the method for manufacturing the wiring substrate of the present embodiment, the seed layer 20 having a thickness of 0.03 μm or more and 0.3 μm or less is formed. When the seed layer 20 having a thickness in this range is formed, it may be possible that effects such as preventing a short circuit and ensuring desired electrical characteristics in the conductor layer formed on the insulating layer 33 can be obtained. Further, it may be possible that an electrolytic plating film (2bb) with less variation in thickness is formed in a subsequent process. A part of the seed layer 20 can be the lower layer (2a) of the conductor layer 24 (see FIG. 2).

As illustrated in FIG. 4D, in the method for manufacturing the wiring substrate of the present embodiment, forming the seed layer 20 may include forming each of a lower film (20a) and an upper film (20b) by sputtering. Each of FIG. 4D and FIGS. 4E-4H to be referenced below illustrates an enlarged view of a state of a portion corresponding to a portion (IVD) illustrated FIG. 4C after undergoing a process described with reference to the each of the drawings. The lower film (20a) is formed directly on the surface (33a) of the insulating layer 33 and on inner wall surfaces of the insulating layer 33 exposed in the through holes (4a). Then, the upper film (20b) is formed on the lower film (20a).

Each of the lower film (20a) and the upper film (20b) may be formed of any material. For example, as the lower film (20a), a sputtering film formed of titanium, nickel, chromium, aluminum, or an alloy of these metals or any other metal and copper may be formed. On the other hand, as the upper film (20b), a sputtering film formed of copper may be formed. By forming the lower film (20a) on the surface (33a) of the insulating layer 33 prior to the upper film (20b), it may be possible that the upper film (20b) firmly bonded to the insulating layer 33 is formed. A part of the lower film (20a) and a part of the upper film (20b) can be respectively the lower film (2aa) and the upper film (2ab) (see FIG. 2) of the lower layer (2a) of the conductor layer formed on the insulating layer 33.

As illustrated in FIG. 4E, a plating resist (R1) having multiple groove-shaped openings (R11) exposing the seed layer 20 is formed on the seed layer 20. In the example of FIG. 4E, the plating resist (R1) is formed that further includes openings (R12) exposing the through holes (4a) covered by the seed layer 20. The plating resist (R1) is formed, for example, by laminating a dry film resist onto the seed layer 20, and the openings (R11, R12) are formed, for example, using a photolithography technology. The openings (R11) are formed in patterns corresponding to the conductor patterns to be included in the conductor layer 24 (see FIG. 4H) formed on the insulating layer 33.

In the method for manufacturing the wiring substrate of the embodiment, each of the multiple openings (R11) formed in the process of FIG. 4E has a width of 5 μm or less and an aspect ratio ((depth of each groove-shaped opening (R11))/(width of each groove-shaped opening (R11))) of 2.0 or more. Further, the multiple openings (R11) have a distance of 7 μm or less between adjacent openings (R11). By providing at least such openings (R11) in the plating resist (R1), the wiring patterns 11 (see FIG. 2) having the above-described minimum wiring width, minimum inter-wiring distance, and aspect ratio can be formed. Preferably, the plating resist (R1) is formed having a thickness (depth of each opening (R11)) exceeding the thickness of the conductor layer 24 to be formed.

As illustrated in FIG. 4F, in the multiple openings (R11) of the plating resist (R1), and in the openings (R12), an electrolytic plating film (2bb) is formed by electrolytic plating using the seed layer 20 as a power feeding layer. In the method of the present embodiment, an electrolytic plating film (2bb) thicker than the plating resist (R1) is formed. For example, an electrolytic plating film (2bb) formed of copper or nickel or the like is formed. A part of the electrolytic plating film (2bb) can be the upper layer (2b) (see FIG. 2) of the conductor layer formed on the insulating layer 33. The via conductors 4 are formed in the through holes (4a) of the insulating layer 33. As in the example of FIG. 4F, the electrolytic plating film (2bb) may be formed to entirely fill the openings (R11, R12) and further have a curved upper surface protruding upward from the upper surface of the plating resist (R1). It may be possible that conductor patterns with desired thickness and aspect ratio can be more reliably formed.

As illustrated in FIG. 4G, a part of the upper surface side of the electrolytic plating film (2bb) including the protruding portion from the upper surface of the plating resist (R1) is removed by polishing. In the method for manufacturing the wiring substrate of the present embodiment, a part of the upper surface side of the plating resist (R1) is also removed by polishing along with the part of the electrolytic plating film (2bb). That is, by polishing, the electrolytic plating film (2bb) and the plating resist (R1) are reduced in thickness. Since the electrolytic plating film (2bb) is polished together with the plating resist (R1), it may be possible that the polishing of the electrolytic plating film (2bb) and the removal of a part thereof can be easily performed. The polishing of the electrolytic plating film (2bb) and the plating resist (R1) is performed, for example, using any method such as CMP. As a result of the polishing, the upper surface of the electrolytic plating film (2bb) can have an arithmetic mean roughness of 0.3 μm or less.

The electrolytic plating film (2bb) is polished until a total thickness of the electrolytic plating film (2bb) and the seed layer 20 reaches a thickness required for the conductor layer 24 (see FIG. 4H) formed on the insulating layer 33, for example, until the total thickness of the electrolytic plating film (2bb) and the seed layer 20 is 15 μm or less. However, in the method for manufacturing the wiring substrate of the present embodiment, in the polishing, the electrolytic plating film (2bb) is polished such that the thickness of the seed layer 20 does not exceed 2.5% of the total thickness of the seed layer 20 and the electrolytic plating film (2bb). As described above, the seed layer 20 having a thickness of 0.03 μm or more and 0.3 μm or less is formed. Therefore, the electrolytic plating film (2bb) is polished to maintain a thickness of at least 4.875 μm. Since the electrolytic plating film (2bb) remains with such a thickness, it may be possible that, in the conductor layer 24 to be formed, wiring patterns with desired low conductor resistance and, as a result, good signal transmission characteristics with little transmission loss can be obtained.

After the polishing of the electrolytic plating film (2bb), the plating resist (R1) is removed. Further, a portion of the seed layer 20 that is not covered by the electrolytic plating film (2bb) is removed, for example by quick etching or the like.

As a result, as illustrated in FIG. 4H, the conductor layer 24 including predetermined conductor patterns, such as the wiring patterns 11, separated from each other is obtained. In this way, in the method for manufacturing the wiring substrate of the present embodiment, forming each conductor layer such as the conductor layer 24 includes: forming the seed layer 20 with a thickness of 0.03 μm or more and 0.3 μm or less on the surface of each insulating layer such as the insulating layer 33 (see FIG. 4D); and forming, on the seed layer 20, the plating resist (R1) with multiple groove-shaped openings (R11) exposing the seed layer 20 (see FIG. 4E). The forming of each conductor layer further includes: forming the electrolytic plating film (2bb) thicker than the plating resist (R1) in the multiple openings (R11) (see FIG. 4F); reducing the thicknesses of the electrolytic plating film (2bb) and the plating resist (R1) by polishing (see FIG. 4G); removing the plating resist (R1); and removing a portion of the seed layer 20 that is not covered by the electrolytic plating film (2bb).

As illustrated in FIG. 41, the insulating layer 34 and the conductor layer 25 are formed on the insulating layer 33 and the conductor layer 24. The insulating layer 34 is formed, for example, using a method similar to the method for forming the insulating layer 33. Further, the conductor layer 25 is formed, for example, using a method similar to the method for forming the conductor layer 24.

As illustrated in FIG. 4J, the insulating layer 35 is formed on the conductor layer 25 and the insulating layer 34, and the conductor posts 5 penetrating the insulating layer 35 are formed. Similar to the formation of the insulating layer 33, the insulating layer 35 is formed, for example, by thermocompression bonding of a film-like epoxy resin. It is also possible that the insulating layer 35 is formed using a method such as spraying or curtain coating using an epoxy resin or polyimide resin or the like containing a photosensitive agent. The conductor posts 5 may be formed using a method including a polishing process after the electrolytic plating described as a method for forming the conductor layer 24, or, for example, using a method for forming a conductor layer, such as a semi-additive method. In the example of FIG. 4J, following the formation of the conductor posts 5 by electrolytic plating, the functional layer 6 is formed on the conductor posts 5 by electrolytic plating using the power feeding layer used for the above-mentioned electrolytic plating. For example, a metal film of one or more layers formed of nickel, tin, palladium, gold, or the like is formed as the functional layer 6.

As illustrated in FIG. 4K, the support 8 is removed. For example, in a state in which the release layer 83 provided in the support 8 has lost its adhesiveness or softened due to heating or ultraviolet irradiation or the like, the base material 81 and the first metal film layer 82 are pulled apart from the second metal film layer 84. After that, the second metal film layer 84 is removed by etching or the like. The surfaces of the conductor layer 21 and the insulating layer 31 on the opposite side with respect to the conductor layer 22 are exposed. Through the above processes, the wiring substrate 1 of the example of FIG. 1 is completed.

### Second Embodiment

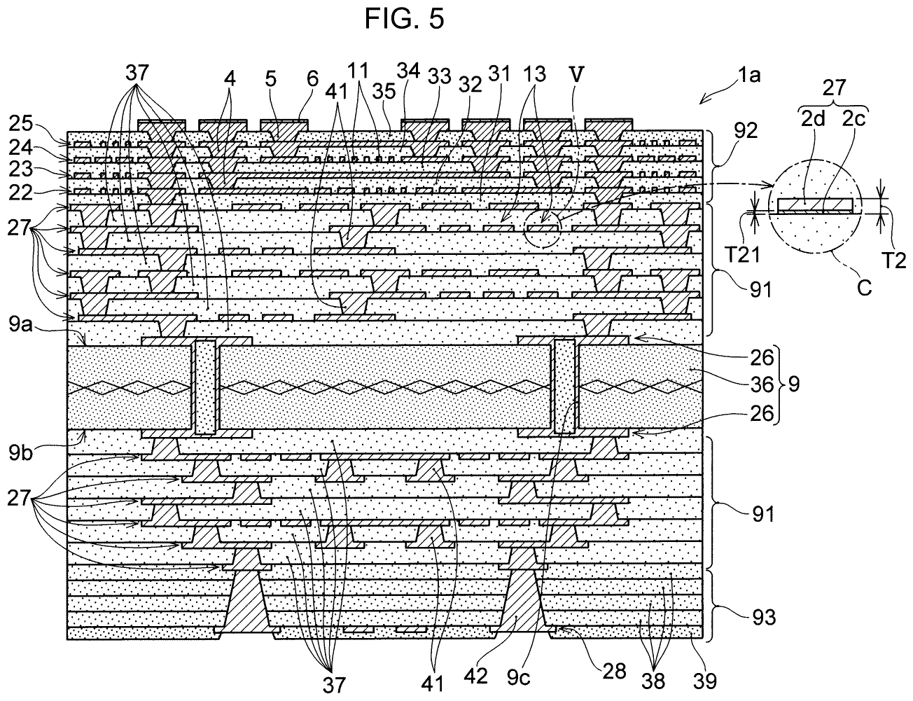

FIG. 5 illustrates a wiring substrate (1a), which is an example of a wiring substrate of another embodiment, which is different from the embodiment of which an example is illustrated in FIG. 1 and the like. As illustrated in FIG. 5, the wiring substrate (1a) includes a core substrate 9, and first build-up parts 91 that are respectively laminated on a first surface (9a) of the core substrate 9 and a second surface (9b) of the core substrate 9 on the opposite side with respect to the first surface (9a). The wiring substrate (1a) includes a second build-up part 92 laminated on the first build-up part 91 on the first surface (9a) side of the core substrate 9, and a third build-up part 93 laminated on the first build-up part 91 on the second surface (9b) side of the core substrate 9. The core substrate 9 includes an insulating layer 36 formed of, for example, an insulating material such as glass epoxy, and conductor layers 26 that are respectively formed on both sides of the insulating layer 36 and are formed of, for example, copper or the like. The two conductor layers 26 are connected to each other by through-hole conductors (9c) that are formed of, for example, copper or the like and penetrate the insulating layer 36.

In the description of the present embodiment in which the wiring substrate (1a) is illustrated as example, in a thickness direction of the wiring substrate (1a), a side farther from the insulating layer 36 is also referred to as an “outer side” or “upper side,” or simply “upper,” and a side closer to the insulating layer 36 is also referred to as an “inner side” or “lower side,” or simply “lower.” Further, for the conductor layers and the insulating layers, a surface facing the opposite side with respect to the insulating layer 36 is also referred to as an “upper surface,” and a surface facing the insulating layer 36 side is also referred to as a “lower surface.” The thickness direction of the wiring substrate (1a) is also referred to as a “Z direction.”

Each of the two first build-up parts 91 is formed of laminated multiple insulating layers 37 and multiple conductor layers 27. In each of the two first build-up parts 91, the insulating layers 37 and the conductor layers 27 are alternately laminated. Each of the first build-up parts 91 includes via conductors 41 that connect the conductor layers 27 separated by the insulating layers 37. Each of the conductor layers 27 may include any conductor patterns such as wiring patterns 13.

On the other hand, the second build-up part 92 is formed by the insulating layers (31-35) and the conductor layers (22-25) included in the embodiment described with reference to FIG. 1 and includes the via conductors 4. In the second build-up part 92, the conductor posts 5 with the functional layer 6 described with reference to FIG. 1 are formed. Repetitive description about the structural elements already described with reference to FIG. 1 is omitted.

In the wiring substrate (1a) of the example of FIG. 5, the third build-up part 93 includes laminated multiple insulating layers 38, a conductor layer 28 that is formed on the outermost insulating layer 38 and includes any conductor patterns, and an insulating layer 39 covering the conductor layer 28. The third build-up part 93 includes via conductors 42 that collectively penetrate the multiple insulating layers 38. The via conductors 42 connect the conductor layer 28 to the outermost conductor layer 27 of the first build-up part 91 on the second surface (9b) side.

Similar to the conductor layers (22-25) described above, the conductor layers 27 and the conductor layer 28 that respectively form the first build-up parts 91 and the third build-up part 93 are formed using any metal such as copper or nickel. As illustrated in a circle (C) illustrating an enlarged view of a portion (V) of FIG. 5, each of these conductor layers includes a lower layer (2c) and an upper layer (2d). Similar to the upper layer (2b) (see FIG. 2) of the conductor layer 24 or the like, the upper layer (2d) is formed of a plating film formed by electrolytic plating. Further, similar to the lower layer (2a) (see FIG. 2) of the conductor layer 24 or the like, the lower layer (2c) is, for example, a sputtering film formed by sputtering, and may be an electroless plating film formed by electroless plating.

However, a thickness (T21) of the lower layer (2c) is larger than 2.5% of a total thickness (T2) of each of the conductor layers 27 (or the conductor layer 28). Further, the lower layer (2c) may be a metal film formed using a method different from the lower layer (2a) of the conductor layers (22-25). For example, when the lower layer (2a) of the conductor layers (22-25) is a sputtering film, the lower layer (2c) of the conductor layers 27 may be an electroless plating film.

Further, a minimum wiring width of the wiring patterns such as the wiring patterns 13 included in the conductor layers (27, 28) is larger than a minimum wiring width of the wiring patterns (for example, the wiring patterns 11) included in any of the conductor layers (22-25). In addition, a minimum distance between the wiring patterns included in the conductor layers (27, 28) is larger than a minimum distance between the wiring patterns (for example, the wiring patterns 11) included in any of the conductor layers (22-25). Further, an aspect ratio of the wiring patterns included in the conductor layers (27, 28) is smaller than an aspect ratio of the wiring patterns (for example, the wiring patterns 11) included in the conductor layers (22-25). Further, in the example of FIG. 5, the upper surfaces of the conductor layers (27, 28) are surfaces that have not undergone a polishing process.

That is, the second build-up part 92 is formed of the conductor layers (22-25) that are different in structure from the conductor layers 27 included in the first build-up parts 91 or the conductor layer 28 included in the third build-up part 93. Further, the second build-up part 92 includes wiring patterns such as the wiring patterns 11 that are formed by a narrower pitch layout rule than wiring patterns such as the wiring patterns 13 included in the first build-up parts 91 and the third build-up part 93.

The wiring substrate of the embodiment, such as the wiring substrate (1a) in the example of FIG. 5, may include conductor layers such as the conductor layers (22-25) that include wiring patterns formed by narrower pitch layout rules, and conductor layers with different structures that include wiring patterns formed by wider pitch layout rules. Further, the wiring substrate of the embodiment may include a build-up part (for example, the first build-up parts 91) formed of one of two types of conductor layers that are designed according to different wiring rules and have different structures as described above, and a build-up part (for example, the second build-up part 92) formed of the other of the two types of conductor layers. For example, it may be possible that a wiring substrate that partially requires fine wiring patterns and good high-frequency transmission characteristics can be realized with a smaller size and/or at a lower cost while satisfying the required characteristics.

Similar to the above-described insulating layers (31-34) that form the second build-up part 92, the insulating layers 37 and the insulating layers 38 that respectively form the first build-up parts 91 and the third build-up part 93 are formed using a thermosetting resin such as an epoxy resin or a thermoplastic resin such as a fluorine resin. Similarly, the insulating layer 39 is formed of the same material as the insulating layer 35 of the second build-up part 92. However, the insulating layers 37 may be formed of a resin different in composition or additive content from the insulating layers (31-34). For example, an insulating material advantageous in high-frequency signal transmission characteristics or in maintaining insulation between wiring patterns may be used for the insulating layers (31-34) of the second build-up part 92, and an insulating material advantageous in workability or cost may be used for the insulating layers 37 of the first build-up parts 91, and the like. As an example, particle sizes of an inorganic filler (not illustrated) such as silica or alumina contained in the insulating layers (31-34) may be smaller than particle sizes of an inorganic filler contained in the insulating layer 38. Further, a relative permittivity of the insulating layers (31-34) may be smaller than a relative permittivity of the insulating layer 38, and a dielectric loss tangent of the insulating layers (31-34) may be smaller than a dielectric loss tangent of the insulating layer 38.

In the third build-up part 93 of the example of FIG. 5, it is not that conductor layers are respectively formed on surfaces of the insulating layers 38. Rather, the conductor layer 28 is formed only on the surface of the outermost insulating layer 38. By omitting formation of conductor layers exceeding a required number of layers, it may be possible that reduction in size and weight and reduction in cost of the wiring substrate (1a) are promoted. In addition, as in the example in FIG. 5, when the same number of insulating layers 38, formed of the same material and having substantially the same thickness as the insulating layers (insulating layers (31-34)) of the second build-up part 92, are formed, it may be possible to suppress warping of the wiring substrate (1a).

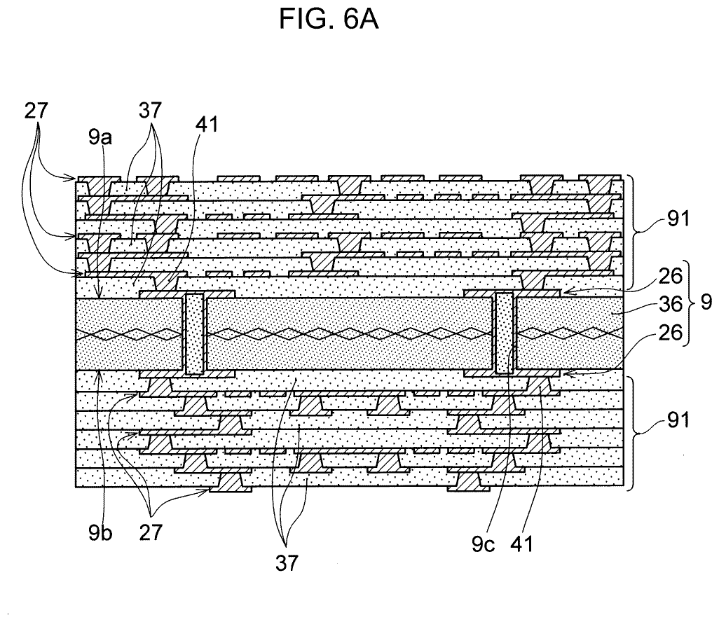

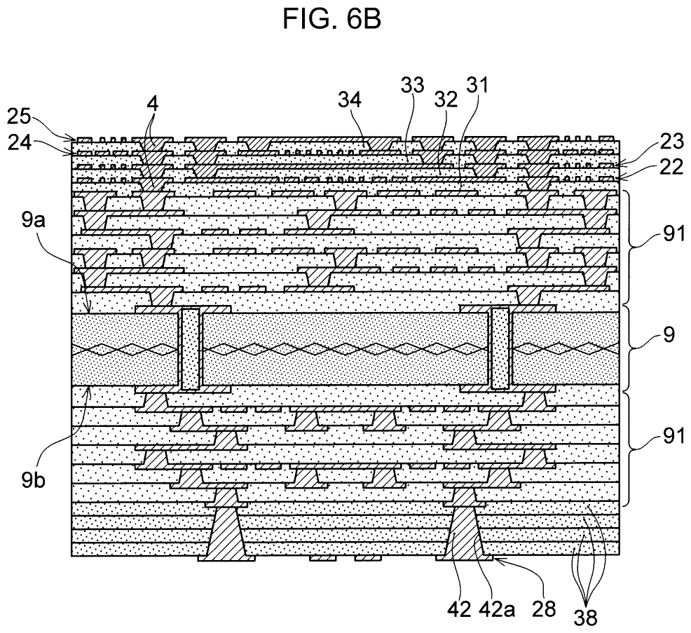

When the wiring substrate (1a) of the example of FIG. 5 is manufactured, first, as illustrated in FIG. 6A, the core substrate 9 is prepared, and the first build-up parts 91 are respectively formed on both sides of the core substrate 9. In preparing the core substrate 9, for example, a double-sided copper-clad laminated plate including the insulating layer 36 is prepared, and, after through holes are formed, for example, by drilling, the through-hole conductors (9c) are formed in the through holes, for example, by electroless plating and electrolytic plating. After inner sides of the through-hole conductors (9c) are filled with an epoxy resin or the like, the conductor layers 26 including predetermined conductor patterns are formed, for example, using a subtractive method including electroless plating and electrolytic plating.

Then, in forming the first build-up parts 91, on each of the first surface (9a) and the second surface (9b) of the core substrate 9, the innermost insulating layer 37 is formed, for example, by thermocompression bonding a film-like insulating resin. Through-holes are formed in the formed insulating layer 37 at formation positions of the via conductors 41 by irradiating CO₂ laser or the like. After that, the innermost conductor layer 27 is formed, for example, using any method for forming a conductor layer, such as a semi-additive method. The via conductors 41 are formed in the through holes formed in the insulating layer 37. Using a similar method, by repeating the formation of the insulating layer 37, the conductor layer 27 and the via conductors 41, the first build-up parts 91 are respectively formed on both sides of the core substrate 9.

As illustrated in FIG. 6B, on the first build-up part 91 on the first surface (9a) side of the core substrate 9, the conductor layers (22-25), the insulating layers (31-34), and the via conductors 4 are formed. The conductor layers (22-25), the insulating layers (31-34), and the via conductors 4 are formed, for example, using the methods described above with reference to FIGS. 4B-4I. On the first build-up part 91 on the second surface (9b) side of the core substrate 9, along with the formation of the insulating layers (31-34), the multiple insulating layers 38 are formed, one layer at a time, using a method similar to the method for forming the insulating layers (31-34). After the formation of the conductor layer 25 on the first surface (9a) side, through holes (42a) are formed that collectively penetrate the multiple insulating layers 38, and further, the conductor layer 28 is formed on the outermost insulating layer 38, for example, using a semi-additive method. Along with the formation of the conductor layer 28, the via conductors 42 are formed in the through holes (42a).

After the formation of the conductor layer 28, for example, using the method described above with reference to FIG. 4J, the insulating layer 35, the conductor posts 5, and the functional layer 6 illustrated in FIG. 5 are formed. On the second surface (9b) side of the core substrate 9, the insulating layer 39 covering the conductor layer 28 is formed along with the formation of the insulating layer 35, for example, using a method similar to the method for forming the insulating layer 35. The wiring substrate (1a) of the example of FIG. 5 is completed.

The wiring substrate of the embodiment is not limited to those having the structures illustrated in the drawings and those having the structures, shapes, and materials exemplified herein. As described above, the wiring substrate of the embodiment may include any number of conductor layers and insulating layers. For example, it is also possible that the wiring substrate of the embodiment includes only one insulating layer and one conductor layer formed on the insulating layer. The conductor posts 5 and the functional layer 6 provided in the wiring substrate 1 and the wiring substrate (1a) illustrated in FIG. 1 or FIG. 5 are not necessarily provided in the wiring substrate of the embodiment. In the example of FIG. 1, it is also possible that only some of the conductor layers (22-25) each have a polished surface.

The method for manufacturing a wiring substrate of the embodiment is not limited the method described with reference to the drawings. For example, as described above, a wiring substrate having any layered structure including any number of layers may be manufactured using the method for manufacturing the wiring substrate of the embodiment. In the method for manufacturing the wiring substrate of the embodiment, the support 8 illustrated FIG. 4A is not necessarily used. Further, a support used in the method for manufacturing the wiring substrate of the embodiment does not necessarily have the structure of the support 8 illustrated in FIG. 4 and the like. In the method for manufacturing the wiring substrate of the embodiment, it is also possible that any process other than the processes described above is added, or some of the processes described above are omitted.

Japanese Patent Application Laid-Open Publication No. 2009-253147 describes a method for forming a wiring on an insulating layer by electrolytic plating. In this method, the wiring is formed by forming a plating film in an opening of a first resist film formed on a seed layer, and, after the first resist film is removed, a second resist film covering the plating film is formed. In a state in which upper and side surfaces of the plating film are covered by the second resist film, an unwanted portion of the seed layer that is not covered by the plating film is removed by wet etching.

In the method for forming a wiring described in Japanese Patent Application Laid-Open Publication No. 2009-253147, in forming multiple wirings formed at a fine pitch, it may be possible that a seed layer exposed between adjacent plating films with a narrow gap is covered by the second resist film and is not reliably removed. As a result, deterioration in insulation or a short circuit failure between the wirings may occur. In addition, when thick plating films are formed in order to form wirings with low conductor resistance, it is thought that a second resist film spanning between sides of plating films is likely to be formed and a seed layer exposed between plating films is more likely to be covered by the second resist film.

A wiring substrate according to an embodiment of the present invention includes an insulating layer, and a conductor layer that is formed on a surface of the insulating layer and includes multiple wiring patterns. A surface of the conductor layer on the opposite side with respect to the insulating layer is a polished surface. The multiple wiring patterns have a minimum wiring width of 5 μm or less. The multiple wiring patterns have a minimum inter-wiring distance of 7 μm or less. Each of the multiple wiring patterns has an aspect ratio of 2.0 or more and 4.0 or less. The conductor layer is formed of an upper layer, which is formed of a plating film, and a lower layer, which is directly formed on the surface of the insulating layer and is a seed layer for the plating film. A ratio of a thickness of the lower layer to a thickness of the conductor layer is 2.5% or less.

A method for manufacturing a wiring substrate according to an embodiment of the present invention includes forming an insulating layer, and forming a conductor layer on a surface of the insulating layer. The forming of the conductor layer includes forming a seed layer having a thickness of 0.03 μm or more and 0.3 μm or less on the surface of the insulating layer, forming, on the seed layer, a plating resist having multiple groove-shaped openings exposing the seed layer, forming, in the multiple openings, an electrolytic plating film thicker than the plating resist, reducing a thickness of the electrolytic plating film and a thickness of the plating resist by polishing, removing the plating resist, and removing a portion of the seed layer that is not covered by the electrolytic plating film. Each of the multiple openings has a width of 5 μm or less and an aspect ratio of 2.0 or more and have a distance of 7 μm or less between adjacent openings. In the polishing, the electrolytic plating film is polished such that the thickness of the seed layer does not exceed 2.5% of a total thickness of the seed layer and the electrolytic plating film.

According to an embodiment of the present invention, it is thought that a wiring substrate is provided that includes wirings that are formed at a fine pitch, has desired insulation between adjacent wirings, and has excellent electrical characteristics.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
an insulating layer; and
a conductor layer formed on a surface of the insulating layer and including a plurality of wiring patterns such that the conductor layer includes an upper layer comprising a plating film and a lower layer comprising a seed layer for the plating film and directly formed on the surface of the insulating layer,
wherein the conductor layer is formed such that a ratio of a thickness of the lower layer to a thickness of the conductor layer is 2.5% or less, the plurality of wiring patterns has a minimum wiring width of 5 μm or less and a minimum inter-wiring distance of 7 μm or less, and each of the wiring patterns has an aspect ratio in a range of 2.0 to 4.0.

2. The wiring substrate according to claim 1, wherein the conductor layer has a thickness of 15 μm or less.

3. The wiring substrate according to claim 1, wherein the conductor layer is formed such that the lower layer has a thickness of 0.3 μm or less.

4. The wiring substrate according to claim 1, wherein the conductor layer is formed such that the lower layer is a sputtering film.

5. The wiring substrate according to claim 4, wherein the conductor layer is formed such that the sputtering film includes a lower film comprising a copper alloy formed on the surface of the insulating layer, and an upper film comprising copper formed on the lower film.

6. The wiring substrate according to claim 5, wherein the conductor layer is formed such that a width of the lower film is smaller than a width of the upper layer and larger than a width of the upper film.

7. The wiring substrate according to claim 1, further comprising:
a via conductor integrally formed with the conductor layer such that the via conductor is penetrating through the insulating layer and connecting a conductor on the insulating layer on an opposite side with respect to the conductor layer and has an aspect ratio in a range of 0.5 to 1.0.

8. The wiring substrate according to claim 1, wherein the conductor layer is formed such that the lower layer has an etched surface exposed on a side surface of each of the wiring patterns.

9. The wiring substrate according to claim 1, wherein the conductor layer is formed such that the polished surface has an arithmetic mean roughness of 0.3 μm or less.

10. The wiring substrate according to claim 2, wherein the conductor layer is formed such that the lower layer has a thickness of 0.3 μm or less.

11. The wiring substrate according to claim 1, wherein the conductor layer has a polished surface on an opposite side with respect to the insulating layer.

12. The wiring substrate according to claim 2, wherein the conductor layer is formed such that the lower layer is a sputtering film.

13. The wiring substrate according to claim 12, wherein the conductor layer is formed such that the sputtering film includes a lower film comprising a copper alloy formed on the surface of the insulating layer, and an upper film comprising copper formed on the lower film.

14. The wiring substrate according to claim 13, wherein the conductor layer is formed such that a width of the lower film is smaller than a width of the upper layer and larger than a width of the upper film.

15. The wiring substrate according to claim 2, further comprising:
a via conductor integrally formed with the conductor layer such that the via conductor is penetrating through the insulating layer and connecting a conductor on the insulating layer on an opposite side with respect to the conductor layer and has an aspect ratio in a range of 0.5 to 1.0.

16. The wiring substrate according to claim 2, wherein the conductor layer is formed such that the lower layer has an etched surface exposed on a side surface of each of the wiring patterns.

17. A method for manufacturing a wiring substrate, comprising:
forming an insulating layer; and
forming a conductor layer on a surface of the insulating layer,
wherein the forming of the conductor layer includes forming a seed layer having a thickness in a range of 0.03 μm to 0.3 μm on the surface of the insulating layer, forming, on the seed layer, a plating resist having a plurality of groove-shaped openings exposing the seed layer, forming, in the plurality of groove-shaped openings, an electrolytic plating film such that each of the groove-shaped openings has a width of 5 μm or less, an aspect ratio of 2.0 or more, and a distance of 7 μm or less between adjacent ones of the groove-shaped openings, polishing the electrolytic plating film and the plating resist such that the thickness of the seed layer does not exceed 2.5% of a total thickness of the seed layer and the electrolytic plating film, removing the plating resist from the seed layer, and removing a portion of the seed layer that is not covered by the electrolytic plating film.

18. The method for manufacturing a wiring substrate according to claim 17, wherein the electrolytic plating film is formed in the plurality of groove-shaped openings such that the electrolytic plating film is thicker than the plating resist and, and the electrolytic plating film and the plating resist are polished such that a thickness of the electrolytic plating film and a thickness of the plating resist are reduced.

19. The method for manufacturing a wiring substrate according to claim 17, wherein the forming of the seed layer includes sputtering a copper alloy directly on the surface of the insulating layer such that a lower film comprising the copper alloy is formed directly on the surface of the insulating layer, and sputtering copper on the lower film such that an upper film comprising the copper is formed on the lower film.

20. The method for manufacturing a wiring substrate according to claim 19, wherein the portion of the seed layer that is not covered by the electrolytic plating film is removed in a single etching process.
